(19) United States
(12) Patent Application Publication
(10) Pub. No.: US 2026/0259501 A1
(43) Pub. Date: Sep. 3, 2026

(54) PHOTOSENSITIVE ELEMENT, RESIST PATTERN FORMATION METHOD, AND PRINTED WIRING BOARD MANUFACTURING METHOD

(71) Applicant: Resonac Corporation, Tokyo (JP)

(72) Inventors: Natsuki TODA, Tokyo (JP); Kenichi IWASHITA, Tokyo (JP); Yosuke KAGUCHI, Tokyo (JP); Hiroshi ONO, Tokyo (JP)

(21) Appl. No.: 18/994,443

(22) PCT Filed: Sep. 28, 2023
(86) PCT No.: PCT/JP2023/035393

§ 371 Date: Jan. 14, 2025

(30) Foreign Application Priority Data
Oct. 3, 2022 (WO) PCT/JP2022/036971

(51) Int. Cl. G03F 7/09; G03F 7/029; G03F 7/033; G03F 7/16; H05K 3/06

(52) U.S. Cl. CPC G03F 7/094; G03F 7/0295; G03F 7/033; G03F 7/161; H05K 3/064

(57) ABSTRACT

A photosensitive element including a support film, a barrier layer, and a photosensitive layer in this order, in which the number of particles with a diameter of 0.8 μm or more measured on a surface of the support film on a barrier layer side is 100 or less per 0.0225 mm².

### TECHNICAL FIELD

The present disclosure relates to a photosensitive element, a method for forming a resist pattern, and a method for manufacturing a printed wiring board.

### BACKGROUND ART

Conventionally, in the field of manufacturing printed wiring boards, as resist materials used in etching, plating or the like, photosensitive elements including a photosensitive resin composition and a layer (hereinafter also referred to as “photosensitive layer”) formed on a support film using the photosensitive resin composition have been widely used.

Printed wiring boards are manufactured using the photosensitive elements described above, for example, by the following procedure. In other words, first, the photosensitive layer of the photosensitive element is laminated onto a substrate for circuit formation such as a copper clad laminate. At this time, the photosensitive layer is laminated so that the surface opposite to the surface in contact with the support film is in close contact with the surface of the substrate for circuit formation on which the circuit is formed. Furthermore, the lamination is performed, for example, by press bonding under heating of the photosensitive layer onto the substrate for circuit formation (normal pressure lamination method).

Next, a desired region of the photosensitive layer is exposed through the support film using a mask film or the like to generate radicals. The generated radicals pass through several reaction paths and contribute to the crosslinking reaction (photocuring reaction) of the photopolymerizable compound. Subsequently, the support film is peeled off, the uncured portion of the photosensitive layer is dissolved or dispersed in a developer for removal, and a resist pattern is thus formed. Next, etching or plating is performed using the resist pattern as a resist to form a conductor pattern, and finally, the photocured portion (resist pattern) of the photosensitive layer is peeled off (removed).

Incidentally, in recent years, with the improvement in the performance of semiconductor packages, there has been a demand for photosensitive elements that can be used to form finer wirings at a higher yield. However, when the photosensitive layer is exposed through the support film as described above, there is a problem in that the obtained resist pattern may have minute deletions and the minute deletions cause a short circuit of wiring and deterioration of yield.

Since the deletions of resist pattern are generated by scattering of exposed light due to particles such as lubricant in the support film, a method for forming an excellent resist pattern by peeling off the support film before exposure and then exposing the photosensitive layer has been studied. However, in a case where the support film is peeled off and then the photosensitive layer is exposed, as the generated radicals come into contact with oxygen in the air, the radicals are rapidly stabilized (deactivated), and the photocuring reaction of the photopolymerizable compound is less likely to proceed. In addition, in a case where a mask is attached to the photosensitive layer during exposure, problems such as damage to the photosensitive layer when the mask is peeled off or contamination of the mask occur. Therefore, in this method, in order to improve the problems, it has been studied to use a photosensitive element including a resin protective layer (barrier layer) between a support film and a photosensitive layer (see, for example, Patent Literatures 1 and 2).

### CITATION LIST

### Patent Literature

Patent Literature 1: Japanese Unexamined Patent Publication No. 2013-505483
Patent Literature 2: Japanese Unexamined Patent Publication No. 2013-505484

### SUMMARY OF INVENTION

### Technical Problem

However, in the case of using a photosensitive element including a barrier layer between a support film and a photosensitive layer as well, it is not always sufficiently possible to suppress the generation of deletions in the obtained resist pattern, and there is room for further improvement.

The present disclosure has been made in view of the problems of the prior art described above, and an object thereof is to provide a photosensitive element that can reduce the number of deletions generated in a resist pattern, a method for forming a resist pattern, and a method for manufacturing a printed wiring board.

### Solution to Problem

As a result of intensive studies to solve the above problems, the present inventors have found out that in a photosensitive element including a barrier layer between a photosensitive layer and a support film, traces of particles such as lubricant contained in the support film remain on the barrier layer surface, the exposed light is scattered by the irregularities of these traces of particles, and deletions are generated in the resist pattern. The present inventors have also found out that these traces of particles can be reduced by using a support film that satisfies predetermined requirements, and thus completed the present invention.

In other words, the present disclosure provides the following photosensitive element, method for forming a resist pattern, and method for manufacturing a printed wiring board.

[1] A photosensitive element including a support film, a barrier layer, and a photosensitive layer in this order, in which a number of particles with a diameter of 0.8 μm or more measured on a surface of the support film on a barrier layer side is 100 or less per 0.0225 mm².

[2] The photosensitive element according to [1], in which a number of particles with a diameter of 0.8 μm or more measured on a surface of the support film on a barrier layer side is 5 or more per 0.0225 mm².

[3] The photosensitive element according to [1] or [2], in which a coefficient of linear thermal expansion of the support film in a TD direction at 80 to 110° C. is 30 ppm/K or more.

[4] The photosensitive element according to [3], in which a coefficient of linear thermal expansion of the support film in a TD direction at 80 to 110° C. is 170 ppm/K or less.

[5] The photosensitive element according to any one of [1] to [4], in which the barrier layer contains a water-soluble resin.

[6] The photosensitive element according to any one of [1] to [5], in which a thickness of the barrier layer is 2 to 12 μm.

[7] The photosensitive element according to any one of [1] to [6], in which a number of particles with a diameter of 5.0 μm or more measured on a surface of the support film on a barrier layer side is 0 per 0.0225 mm².

[8] A method for forming a resist pattern, the method including: a step of disposing a photosensitive layer, a barrier layer, and a support film on a substrate in this order from a substrate side using the photosensitive element according to any one of [1] to [7]; a step of removing the support film and exposing the photosensitive layer to active light rays through the barrier layer; and a step of removing an uncured portion of the photosensitive layer and the barrier layer from the substrate.

[9] A method for manufacturing a printed wiring board, the method including a step of forming a conductor pattern by etching or plating a substrate on which a resist pattern is formed by the method for forming a resist pattern according to [8].

### Advantageous Effects of Invention

According to the present disclosure, it is possible to provide a photosensitive element that can reduce the number of deletions generated in a resist pattern, a method for forming a resist pattern, and a method for manufacturing a printed wiring board.

### BRIEF DESCRIPTION OF DRAWINGS

FIG. 1 is a schematic cross-sectional view illustrating an embodiment of a photosensitive element of the present disclosure.

FIG. 2 is a view schematically illustrating an example of a printed wiring board manufacturing process by a semi-additive method.

### DESCRIPTION OF EMBODIMENTS

Hereinafter, suitable embodiments of the present disclosure will be described in detail with reference to the drawings if necessary. It goes without saying that in the following embodiments, the constituent elements (including elemental steps and the like) are not necessarily essential except in cases where they are specifically stated or where they are clearly considered essential in principle. This also applies to numerical values and ranges, and should not be construed as unduly limiting the present disclosure.

Meanwhile, (meth)acrylic acid in this specification means at least one of acrylic acid or methacrylic acid corresponding thereto. Furthermore, the same applies to other similar expressions such as (meth)acrylate. The materials exemplified below may be used singly or in combination of two or more kinds thereof unless otherwise stated. In a case where a plurality of substances corresponding to each component are present in a composition, the content of each component in the composition means the total amount of the plurality of substances present in the composition unless otherwise stated.

In this specification, the term “step” is used not only to refer to an independent step, but also to include a step in which the intended action of the step is achieved even if the step cannot be clearly distinguished from other steps.

Furthermore, in this specification, a numerical range indicated using “to” indicates a range that includes the numerical values written before and after “to” as the minimum and maximum values, respectively. In addition, in numerical ranges described stepwise in this specification, the upper limit value or lower limit value of the numerical range of a certain stage may be replaced with the upper limit value or lower limit value of the numerical range of another stage. In addition, in a numerical range described in this specification, the upper limit value or lower limit value of the numerical range may be replaced with the value indicated in Examples. In addition, in this specification, the term “layer” includes not only a structure of a shape formed on the entire surface but also a structure of a shape formed on a part of the surface when observed in a plan view.

### [Photosensitive Element]

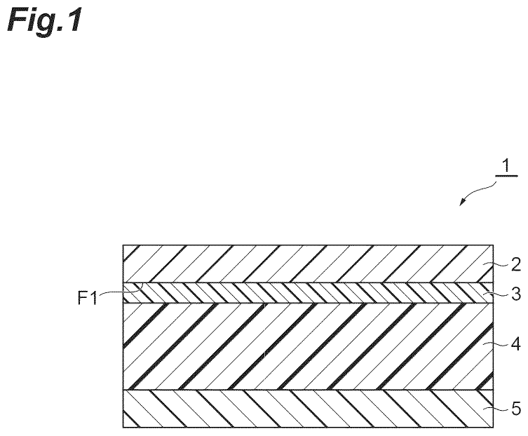

As illustrated in FIG. 1, a photosensitive element 1 of the present embodiment includes a support film 2, a barrier layer 3, and a photosensitive layer 4 in this order, and may further include other layers such as a protective layer 5. In addition, the number of particles with a diameter of 0.8 μm or more measured on a surface F1 of the support film 2 on the barrier layer 3 side is 100 or less per 0.0225 mm². Hereinafter, each layer in the photosensitive element according to the present embodiment will be described in detail.

### <Support Film>

Examples of the support film of the present embodiment include polyester films such as polyethylene terephthalate (PET), polybutylene terephthalate (PBT), and polyethylene-2,6-naphthalate (PEN); and polyolefin films such as polypropylene and polyethylene. Among these, a polyester film may be used. By using a polyester film as the support film, there is a tendency that the mechanical strength and resistance to heat of the support film can be improved. Furthermore, by using a polyester film, there is a tendency that poor quality such as wrinkling of the barrier layer that occurs when the barrier layer is formed on the support film can be suppressed, and workability can be improved. In addition, from the viewpoint of enhancing slipperiness and winding properties, a polyester film containing particles (such as a lubricant) may be used. In the case of using a polyester film containing particles (such as a lubricant), the barrier layer may be formed on the surface on the side having the particles (such as a lubricant). As such a polyester film, for example, a polyester film in which particles (such as a lubricant) are kneaded, a polyester film in which a layer containing particles (such as a lubricant) is formed on both surfaces, or a polyester film in which a layer containing particles (such as a lubricant) is formed on one surface may be used. Noted that, the support film may be single layer or multilayer.

Examples of the method for adding particles such as a lubricant to the support film include a method in which particles (such as a lubricant) are kneaded into the support film, and a method in which a layer containing particles (such as a lubricant) is formed on the support film by a known method such as roll coating, flow coating, spray coating, curtain flow coating, dip coating, or slit die coating.

In the support film, the number of particles (such as a lubricant) with a diameter of 0.8 μm or more measured on the surface F1 on the side where the barrier layer is formed is 100 or less per 0.0225 mm². By using a support film that satisfies the requirement, it is possible to prevent traces of particles contained in the support film from remaining on the barrier layer surface and to reduce the number of deletions generated in the resist pattern. Furthermore, by using a support film that satisfies the requirement, the LER (line edge roughness) of the resist pattern can be reduced. The number of particles may be 85 or less, 70 or less, 50 or less, 30 or less, or 20 or less from the viewpoint of further reducing the number of deletions generated in the resist pattern and further reducing LER. The lower limit of the number of particles is not particularly limited, and may be 0 or may be 5 or more or 10 or more. A support film that satisfies the requirement regarding the number of particles can be obtained by adjusting the particle size and amount of particles (such as a lubricant) contained in the support film, by forming the support film into a multilayer structure and adjusting the presence or absence of particles in each layer, the particle size and content of particles, the thickness of each layer, and the like, or the like. Noted that, the number of particles (such as a lubricant) with a diameter of less than 0.8 μm measured on the surface F1 of the support film is not particularly limited.

The number of particles (such as a lubricant) with a diameter of 0.8 μm or more per 0.0225 mm² measured on the surface F1 on the side where the barrier layer is formed can be measured, for example, using a laser microscope under the following conditions. Noted that, the measuring instrument is not limited to the following instrument.

### —Measurement Conditions—

Instrument: Hybrid laser microscope (manufactured by Lasertec Corporation, product name: OPTELICS HYBRID)
Measurement range: 150 μm square
Measurement details: A luminance image of the surface F1 of the support film is acquired. The acquired luminance image is binarized and the size and number of particles (lubricant) are measured. The number of particles with a diameter of 0.8 μm or more in the measurement range of 150 μm square (0.0225 mm²) is calculated.

In the support film, the number of particles (such as a lubricant) with a diameter of 0.8 μm or more per 0.0225 mm² on the surface F1 on the side where the barrier layer is formed may be different from that on the surface opposite to the surface F1. In the support film, the number of particles (such as a lubricant) with a diameter of 0.8 μm or more per 0.0225 mm² measured on the surface opposite to surface F1 may be greater than 100. This makes it possible to further enhance the slipperiness and winding properties of the support film as well as to obtain the effect of the present disclosure of reducing the number of deletions generated in the resist pattern.

In the support film, the number of particles (such as a lubricant) with a diameter of 5.0 μm or more measured on the surface F1 on the side where the barrier layer is formed may be 0 per 0.0225 mm². By using a support film having 100 or less particles with a diameter of 0.8 μm or more and 0 particles with a diameter of 5.0 μm or more per 0.0225 mm² as the number of particles measured on the surface F1, it is possible to further prevent traces of particles contained in the support film from remaining on the barrier layer surface and to further reduce the number of deletions generated in the resist pattern. Furthermore, by using a support film that satisfies the requirement, the LER (line edge roughness) of the resist pattern can be further reduced. The support film may not contain (not be observed) particles (such as a lubricant) with a diameter of 5.0 μm or more in the surface F1, or the entire support film may not contain particles (such as a lubricant) with a diameter of 5.0 μm or more. The number of particles with a diameter of 5.0 μm or more can be measured in the same manner as for measurement of the number of particles with a diameter of 0.8 μm or more.

The haze of the support film may be 0.01 to 5.0%, 0.01 to 1.5%, 0.01 to 1.0%, or 0.01 to 0.5%. The haze of the support film may be less than 0.5%. The support film itself tends to be easily manufactured as this haze is 0.01% or more, and foreign matter in the photosensitive layer tends to be easily detected when the photosensitive layer of the photosensitive element is formed as this haze is 5.0% or less. Here, “haze” means the degree of cloudiness. Haze in the present disclosure refers to a value measured using a commercially available haze meter (turbidity meter) in conformity with the method prescribed in JIS K7105. Haze can be measured, for example, using a commercially available turbidity meter such as NDH-5000 (manufactured by NIPPON DENSHOKU INDUSTRIES CO., LTD., product name).

The coefficient of linear thermal expansion (CTE) of the support film in the TD direction (transverse direction) at 80 to 110° C. may be 30 ppm/K or more, 40 ppm/K or more, or 45 ppm/K or more or may be 170 ppm/K or less, 150 ppm/K or less, or 125 ppm/K or less. When the coefficient of linear thermal expansion is 30 ppm/K or more, the support film and the photosensitive layer are sufficiently deformed when the photosensitive layer is laminated on the substrate together with the support film, and the generation of voids between the photosensitive layer and the substrate can be suppressed. The voids cause deletions in the resist pattern after exposure of the photosensitive layer. Therefore, by suppressing the generation of voids, the number of deletions generated in the resist pattern can be further reduced. Meanwhile, when the coefficient of linear thermal expansion is 170 ppm/K or less, wrinkles generated during lamination can be suppressed. The coefficient of linear thermal expansion of the support film in the TD direction at 80 to 100° C. can be measured using a thermomechanical analyzer, for example, by the method described in Examples.

The thickness of the support film may be 1 to 200 μm, 1 to 100 μm, 1 to 60 μm, 5 to 60 μm, 10 to 60 μm, 10 to 50 μm, 10 to 40 μm, 10 to 30 μm, or 10 to 25 μm. As the thickness of the support film is 1 μm or more, it tends to be possible to prevent the support film from being torn when the support film is peeled off. Furthermore, as the thickness of the support film is 200 μm or less, economic benefits tend to be easily obtained.

### <Barrier Layer>

The photosensitive element of the present embodiment includes a barrier layer between a support film and a photosensitive layer. The oxygen transmission rate of the barrier layer may be 6000 mL/m²·day·MPa or less (value equivalent to a film thickness of 25 μm) in an environment of 20° C. and 65% RH. The barrier layer may be a layer formed using a resin composition for barrier layer formation. The resin composition for barrier layer formation of the present embodiment may contain a water-soluble resin. Furthermore, the barrier layer may be soluble in water or may be soluble in a developer. Noted that, from the viewpoint of being possible to further improve the gas barrier properties of the barrier layer, the adhesive force between the support film and the barrier layer may be smaller than the adhesive force between the barrier layer and the photosensitive layer. In this case, when the support film is peeled off from the photosensitive element, unintended peeling of the barrier layer and the photosensitive layer from each other can be suppressed.

### (Water-Soluble Resin)

The barrier layer may contain a water-soluble resin. Here, “water-soluble resin” means a resin of which the solubility in 100 mL of hexane at 25° C. is 5 g/100 mL-C₆H₁₄ or less. This solubility can be determined by mixing hexane at 25° C. with a dried water-soluble resin and examining the presence or absence of cloudiness. Specifically, a sample 1 obtained by placing a liquid mixture of A (g) of the dried water-soluble resin and 100 mL of hexane in a colorless and transparent glass container with a ground glass stopper, and a sample 2 obtained by placing only 100 mL of hexane in the glass container are each prepared.

Subsequently, the samples in the glass containers are thoroughly shaken, and then it is examined whether the bubbles have disappeared. Immediately after the examination, the two containers are placed side by side under diffused daylight or light equivalent to that, and the liquid state of the sample 1 and the liquid state of the sample 2 are compared with each other. The sample 1 and the sample 2 are compared with each other, and the added amount A (g) when it is observed that the sample 1 begins to become cloudier or the solid component begins to float is defined as the solubility of the water-soluble resin in 100 mL of hexane at 25° C.

Examples of the water-soluble resin include polyvinyl alcohol, polyvinylpyrrolidone, and water-soluble polyimides. From the viewpoint of further improving the gas barrier properties of the barrier layer and further suppressing the deactivation of radicals generated by the active light rays used for exposure, the water-soluble resin may include polyvinyl alcohol. Polyvinyl alcohol can be obtained, for example, by saponifying polyvinyl acetate obtained by polymerizing vinyl acetate. The degree of saponification of the polyvinyl alcohol used in the present embodiment may be 50 mol % or more, 70 mol % or more, or 80 mol % or more. Noted that, the upper limit of this degree of saponification is 100 mol %. By containing polyvinyl alcohol having a degree of saponification of 50 mol % or more, there is a tendency that the gas barrier properties of the barrier layer are further improved and the resolution of the formed resist pattern can be further improved. Meanwhile, the “degree of saponification” in this specification refers to a value measured in conformity with JIS K 6726 (1994) (test method for polyvinyl alcohol) prescribed by the Japanese Industrial Standards.

Two or more kinds of polyvinyl alcohols having different degrees of saponification, viscosities, degrees of polymerization, modified species, and the like may be used concurrently. The average degree of polymerization of polyvinyl alcohol may be 300 to 5000, 300 to 3500, or 300 to 2000. Furthermore, the water-soluble resins can be used singly or in combination of two or more kinds thereof. The water-soluble resin may include, for example, polyvinyl alcohol and polyvinylpyrrolidone. In this case, the mass ratio of polyvinyl alcohol to polyvinylpyrrolidone (PVA:PVP) may be 40:60 to 90:10, 50:50 to 90:10, or 60:40 to 90:10.

The content of the water-soluble resin in the resin composition for barrier layer formation of the present embodiment may be 50 to 300 parts by mass, 60 to 250 parts by mass, 70 to 200 parts by mass, 80 to 150 parts by mass, or 80 to 125 parts by mass with respect to 500 parts by mass of water from the viewpoint of improving gas barrier properties.

The content of the water-soluble resin in the barrier layer may be 99.0 to 99.95% by mass, 99.3 to 99.9% by mass, or 99.5 to 99.8% by mass based on the total solid component amount in the barrier layer from the viewpoint of improving gas barrier properties, peelability of the support film and barrier layer from each other, and solubility in a developer.

### (Leveling Agent)

The barrier layer may contain a leveling agent. The leveling agent is oriented on the coating film surface and uniforms the surface tension of the coating film. Examples of the kind of leveling agent include acrylic polymers, vinyl-based leveling agents, silicone-based leveling agents, and fluorine-based leveling agents. The leveling agent is preferably an acrylic polymer from the viewpoint of transferability to the photosensitive element and solubility in a developer. From the viewpoint of keeping the adhesive properties between the barrier layer and the support film in a suitable range and keeping the adhesive force between the support film and the barrier layer smaller than the adhesive force between the barrier layer and the photosensitive layer as well as suppressing unintended peeling of the respective layers from each other and from the viewpoint of easily suppressing defects on the barrier layer surface (hardly causing cissing) when the barrier layer is formed on the support film, the acrylic polymer preferably includes a copolymer having a structural unit derived from at least one selected from the group consisting of butyl (meth)acrylate, isobutyl (meth)acrylate, and terminal methoxy group EO-modified (meth)acrylate, more preferably includes a copolymer having structural units derived from butyl (meth)acrylate and isobutyl (meth)acrylate, and still more preferably includes a copolymer having structural units derived from butyl (meth)acrylate, isobutyl (meth)acrylate, and terminal methoxy group EO-modified (meth)acrylate.

The content of each structural unit constituting the acrylic polymer may be, for example, in the following range based on the total amount of structural units. The content of the structural unit derived from butyl (meth)acrylate may be 2 to 20% by mass, 5 to 15% by mass, or 5 to 10% by mass from the viewpoint of further reducing the number of defects on the barrier layer surface and from the viewpoint of further suppressing deletion of the barrier layer when the support film is peeled off. The content of the structural unit derived from isobutyl (meth)acrylate may be 40 to 80% by mass, 50 to 70% by mass, or 55 to 65% by mass from the viewpoint of further reducing the number of defects on the barrier layer surface and from the viewpoint of further suppressing deletion of the barrier layer when the support film is peeled off. The content of the structural unit derived from the terminal methoxy group-EO modified (meth)acrylate may be 15 to 45% by mass, 20 to 40% by mass, or 25 to 35% by mass from the viewpoint of further reducing the number of defects on the barrier layer surface and from the viewpoint of further suppressing deletion of the barrier layer when the support film is peeled off. Furthermore, the weight average molecular weight of the acrylic polymer may be 10000 to 40000 or 10000 to 20000 from the viewpoint of further reducing the number of defects on the barrier layer surface and from the viewpoint of further suppressing deletion of the barrier layer when the support film is peeled off.

The content of the leveling agent in the barrier layer may be 0.05 to 1.0% by mass, 0.1 to 0.7% by mass, or 0.2 to 0.5% by mass based on the total solid component amount in the barrier layer from the viewpoint of further reducing the number of defects on the barrier layer surface and from the viewpoint of further suppressing deletion of the barrier layer when the support film is peeled off.

### (Ultraviolet Absorber)

The barrier layer may contain an ultraviolet absorber. Ultraviolet absorbers (UV absorbers) are compounds that have a light absorption band in the wavelength range of 300 to 400 nm. The ultraviolet absorber may be water-soluble. The ultraviolet absorber may have a maximum absorption wavelength in the wavelength range of 250 to 500 nm from the viewpoint of further improving resolution. By containing these ultraviolet absorbers, resolution can be improved.

The i-line absorption rate of the ultraviolet absorber may be 5 to 95%, 10 to 90%, or 15 to 75%. The i-line absorption rate can be measured by an ultraviolet-visible spectrophotometer.

The ultraviolet absorbers may be used singly or in combination of two or more kinds thereof. Furthermore, the solubility of the ultraviolet absorber in water at 20° C. may be 0.01 g/100 mL-H₂O or more, 0.1 g/100 mL-H₂O or more, or 1 g/100 mL-H₂O or more from the viewpoint of suppressing aggregation and precipitation of the ultraviolet absorber in the barrier layer.

Examples of the ultraviolet absorber include oxybenzophenone compounds, triazole compounds, benzotriazole compounds, salicylic acid ester compounds, benzophenone compounds, diphenyl acrylate compounds, cyanoacrylate compounds, diphenyl cyanoacrylate compounds, and iron or nickel complex salt compounds. Among these, from the viewpoint of further improving resolution, oxybenzophenone compounds and benzophenone compounds are preferred, benzophenone sulfonic acid compounds are more preferred, and oxybenzophenone sulfonic acid compounds are still more preferred. Noted that, “benzophenone sulfonic acid compounds” are compounds having a sulfo group in benzophenone compounds, and the benzophenone sulfonic acid compounds may be hydrates. It is speculated that as these compounds have a hydrophilic sulfo group in the benzophenone skeleton, the affinity of the benzophenone skeleton for the resist increases as well as the affinity of the sulfo group for the barrier layer increases, and it is possible to achieve both resolution and removability of the barrier layer. Furthermore, among the oxybenzophenone compounds, 2-hydroxy-4-methoxybenzophenone-5-sulfonic acid hydrate represented by the following Formula (1) is preferred.

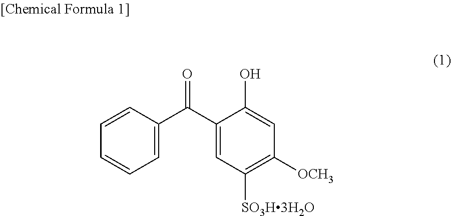

The barrier layer of the present embodiment may have an absorbance of 0.01 to 2.0 or 0.1 to 1.0 for light having a wavelength of 365 nm. Superior resolution tends to be acquired when the absorbance is 0.01 or more, and the resist pattern shape of the obtained resist pattern tends to be more favorable when the absorbance is 2.0 or less. The absorbance of the barrier layer can be measured using, for example, a UV spectrophotometer (Spectrophotometer U-3310, manufactured by Hitachi, Ltd.). The measurement is performed by placing a laminated film in which a barrier layer having any thickness is formed on a support film on the measurement side, placing a support film on the reference side, continuously measuring the absorbance at wavelengths of 300 to 700 nm in absorbance mode, and reading the value at a wavelength of 365 nm.

### (Other Components)

The resin composition for barrier layer formation of the present embodiment may contain an alcohol having 3 or more carbon atoms. The alcohol having 3 or more carbon atoms may be a monohydric alcohol or a polyhydric alcohol (excluding the polyhydric alcohol compounds as a plasticizer described below). The alcohol having 3 or more carbon atoms may contain at least one selected from the group consisting of compounds represented by the following Chemical Formulas (2) to (4) and compounds represented by the following General Formula (5). By containing these alcohols having 3 or more carbon atoms, the peelability of the barrier layer and the support film from each other can be improved. Therefore, in the case of peeling off the support film from the photosensitive element, unintended peeling of the barrier layer and the photosensitive layer from each other can be suppressed and decreases in gas barrier properties and resolution caused by such unintended peeling can be suppressed.

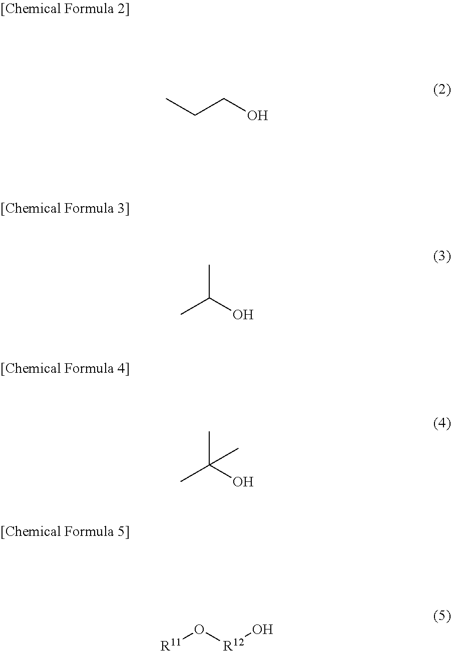

In General Formula (5), R¹¹ represents an alkyl group, and R¹² represents an alkylene group. Furthermore, the sum of the numbers of carbon atoms in the R¹¹ group and the R¹² group is 3 or more. In addition, the sum of the numbers of carbon atoms in the R¹¹ group and the R¹² group may be 10 or less, 8 or less, 7 or less, or 5 or less from the viewpoint of further improving the affinity for water. The alkyl group represented by R¹¹ may be an alkyl group having 1 to 4 carbon atoms, and the alkylene group represented by R¹² may be an alkylene group having 1 to 3 carbon atoms. In addition, the alcohol having 3 or more carbon atoms represented by General Formula (5) may be 2-butoxy-ethanol or 1-methoxy-2-propanol.

The alcohols having 3 or more carbon atoms may be used singly or in combination of two or more kinds thereof. Furthermore, the solubility of the alcohol having 3 or more carbon atoms in water at 20° C. may be 300 mL/100 mL-H₂O or more, 500 mL/100 mL-H₂O or more, or 1000 mL/100 mL-H₂O or more from the viewpoint of further suppressing layer separation of the barrier layer.

In this specification, the “solubility of an alcohol having 3 or more carbon atoms in water at 20° C.” can be determined by mixing the alcohol with water at 20° C. and examining the presence or absence of cloudiness. Specifically, a sample 3 obtained by placing a liquid mixture of A mL of the alcohol and 100 ml of water in a colorless and transparent glass container with a ground glass stopper and a sample 4 obtained by placing only water (100 mL) in the glass container are each prepared. Subsequently, the sample 3 and the sample 4 in the glass containers are each thoroughly shaken, and then it is examined whether the bubbles have disappeared. Immediately after the examination, the two containers are placed side by side under diffused daylight or light equivalent to that, and the liquid state in the sample 3 and the liquid state in the sample 4 are compared with each other. The sample 3 and the sample 4 are compared with each other, and the amount A mL of the alcohol added when the sample 3 is observed to be cloudier is defined as the solubility of the alcohol in water at 20° C.

The content of the alcohol having 3 or more carbon atoms in the resin composition for barrier layer formation of the present embodiment may be 100 to 500 parts by mass or 125 to 450 parts by mass with respect to 500 parts by mass of water. The peelability of the formed barrier layer and the support film from each other tends to be improved when this content is 100 parts by mass or more, and there is a tendency that the solubility of the water-soluble resin is improved and the barrier layer is likely to be formed when this content is 500 parts by mass or less.

The content of the alcohol having 3 or more carbon atoms in the barrier layer of the present embodiment may be more than 0% by mass and 2.0% by mass or less, 0.001 to 2.0% by mass, or 0.005 to 1.0% by mass based on the total amount of the barrier layer (total solid component amount in the resin composition for barrier layer formation, which is used to form the barrier layer). There is a tendency that the diffusion of the alcohol in subsequent steps can be suppressed as this content is 2.0% by mass or less, and the peelability of the barrier layer and the support film from each other tends to be improved as this content is 0.001% by mass or more.

The resin composition for barrier layer formation of the present embodiment may contain an alcohol having less than 3 carbon atoms.

In the case of containing an alcohol having less than 3 carbon atoms, the content thereof may be 125 to 375 parts by mass or 150 to 325 parts by mass with respect to 500 parts by mass of water. There is a tendency that the solubility of the water-soluble resin is improved and the barrier layer is likely to be formed as this content is 125 parts by mass or more, and the peelability of the formed barrier layer and the support film from each other tends to be improved as this content is 375 parts by mass or less. Furthermore, the content of the alcohol having less than 3 carbon atoms in the barrier layer of the present embodiment may be 0.1 to 10% by mass based on the total amount of alcohols having 3 or more carbon atoms in the barrier layer (that is, the amount of alcohols having less than 3 carbon atoms is 0.1 to 10 parts by mass with respect to 100 parts by mass of the total amount of alcohols having 3 or more carbon atoms) from the viewpoint of improving the peelability of the barrier layer and the support film from each other.

Furthermore, the barrier layer and the resin composition for barrier layer formation of the present embodiment may contain known additives such as a plasticizer and a surfactant as long as the effects of the present disclosure are not impaired. In addition, a peeling accelerator may be contained as long as the effects of the present disclosure are not impaired.

The barrier layer in the photosensitive element of the present embodiment can be formed, for example, by applying the resin composition for barrier layer formation of the present embodiment onto a support film and performing drying. In a case where the resin composition for barrier layer formation contains a leveling agent, when the resin composition for barrier layer formation is applied onto a support film, the leveling agent tends to be unevenly distributed on the surface side of the support film in the coating film. Thus, the surface tension of the resin composition for barrier layer formation is likely to decrease, and cissing is likely to be suppressed. Furthermore, as the leveling agent is unevenly distributed on the surface side of the support film in the barrier layer, the adhesive force between the support film and the barrier layer is likely to decrease.

The thickness of the barrier layer is not particularly limited. The thickness of the barrier layer may be 12 μm or less, 10 μm or less, 8 μm or less, 7 μm or less, or 6 μm or less from the viewpoint of easy removal of the barrier layer. Furthermore, the thickness of the barrier layer may be 1.0 μm or more, 1.5 μm or more, 2 μm or more, 3 μm or more, or 4 μm or more from the viewpoint of easy formation of the barrier layer and resolution. In addition, from the viewpoint of suppressing migration of the barrier layer, the thickness of the barrier layer may be 2 μm or more, 3 μm or more, or 4 μm or more.

### <Photosensitive Layer>

The photosensitive layer of the present embodiment is a layer formed using a photosensitive resin composition described below. The photosensitive resin composition can be used depending on the desired purpose as long as the properties thereof change (for example, photocured) when the composition is irradiated with light, and may be negative-type or positive-type. The photosensitive resin composition may contain (A) a binder polymer, (B) a photopolymerizable compound, and (C) a photopolymerization initiator. Furthermore, the photosensitive resin composition may contain (D) a photosensitizer, (E) a polymerization inhibitor, or other components if necessary. Hereinafter, each component used in the photosensitive resin composition in the present embodiment will be described in more detail.

### ((A) Binder Polymer)

(A) The binder polymer (hereinafter also referred to as “component (A)”) can be produced, for example, by radical polymerizing a polymerizable monomer. Examples of the polymerizable monomer include styrene, vinyltoluene, and polymerizable styrene derivatives substituted at the α-position or aromatic ring, such as «-methylstyrene, acrylamides such as diacetone acrylamide, acrylonitrile, vinyl alcohol ethers such as vinyl-n-butyl ether, (meth)acrylic acid alkyl ester, (meth)acrylic acid benzyl ester such as benzyl methacrylate, (meth)acrylic acid tetrahydrofurfuryl ester, (meth)acrylic acid dimethylaminoethyl ester, (meth)acrylic acid diethylaminoethyl ester, (meth)acrylic acid glycidyl ester, 2,2,2-trifluoroethyl (meth)acrylate, 2,2,3,3-tetrafluoropropyl (methacrylate, (meth)acrylic acid, a-bromoacrylic acid, a-chloroacrylic acid, B-furyl (meth)acrylic acid, β-styryl (meth)acrylic acid, maleic acid, maleic anhydride, maleic acid monoesters such as monomethyl maleate, monoethyl maleate, and monoisopropyl maleate, fumaric acid, cinnamic acid, a-cyanocinnamic acid, itaconic acid, crotonic acid, and propiolic acid. These can be used singly or in combination of two or more kinds thereof.

Among these, (meth)acrylic acid alkyl esters may be contained from the viewpoint of improving plasticity. Examples of the (meth)acrylic acid alkyl esters include compounds represented by the following General Formula (II) and compounds obtained by substituting the alkyl groups of these compounds with a hydroxyl group, an epoxy group, a halogen group, and the like.

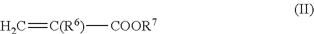

In General Formula (II), R⁶ represents a hydrogen atom or a methyl group, and R⁷ represents an alkyl group having 1 to 12 carbon atoms. Examples of the alkyl group having 1 to 12 carbon atoms represented by R⁷ include a methyl group, an ethyl group, a propyl group, a butyl group, a pentyl group, a hexyl group, a heptyl group, an octyl group, a nonyl group, a decyl group, an undecyl group, a dodecyl group, and structural isomers of these groups.

Examples of the (meth)acrylic acid alkyl esters represented by General Formula (II) include (meth)acrylic acid methyl ester, (meth)acrylic acid ethyl ester, (meth)acrylic acid propyl ester, (meth)acrylic acid butyl ester, (meth)acrylic acid pentyl ester, (meth)acrylic acid hexyl ester, (meth)acrylic acid heptyl ester, (meth)acrylic acid octyl ester, (meth)acrylic acid 2-ethylhexyl ester, (meth)acrylic acid nonyl ester, (meth)acrylic acid decyl ester, (meth)acrylic acid undecyl ester, and (meth)acrylic acid dodecyl ester. These can be used singly or in combination of two or more kinds thereof. Furthermore, the component (A) may contain a carboxyl group

from the viewpoint of alkali developability. The component (A) containing a carboxyl group can be produced, for example, by radical polymerizing a polymerizable monomer having a carboxyl group and another polymerizable monomer. The polymerizable monomer having a carboxyl group may be (meth)acrylic acid or may be methacrylic acid. In addition, the acid value of the component (A) containing a carboxyl group may be 50 to 250 mgKOH/g, 50 to 200 mgKOH/g, or 100 to 200 mgKOH/g.

The carboxyl group content in the component (A) (the blending ratio of the polymerizable monomer having a carboxyl group to the total amount of polymerizable monomers used in the binder polymer) may be 12 to 50% by mass, 12 to 40% by mass, 15 to 35% by mass, 15 to 30% by mass, or 20 to 30% by mass from the standpoint of improving alkali developability and alkali resistance in a well-balanced manner. The alkali developability tends to be improved when this carboxyl group content is 12% by mass or more, and the alkali resistance tends to be excellent when the carboxyl group content is 50% by mass or less.

Meanwhile, the content of the structural unit derived from the polymerizable monomer having a carboxyl group in the component (A) correlates with the blending ratio of the polymerizable monomer having a carboxyl group, and thus may be 12 to 50% by mass, 12 to 40% by mass, 15 to 35% by mass, 15 to 30% by mass, or 20 to 30% by mass.

Furthermore, in the component (A), styrene or a styrene derivative may be used as a polymerizable monomer from the standpoint of adhesive properties and chemical resistance. In the case of using the styrene or styrene derivative as a polymerizable monomer, the content thereof (blending ratio of styrene or styrene derivative to the total amount of polymerizable monomers used in the component (A)) may be 10 to 60% by mass, 15 to 50% by mass, 30 to 50% by mass, 35 to 50% by mass, or 40 to 50% by mass from the standpoint of exhibiting more favorable adhesive properties and chemical resistance. The adhesive properties tend to be improved when this content is 10% by mass or more, and there is a tendency that the peeled pieces can be prevented from increasing in size during development and the time required for peeling is prevented from increasing when this content is 60% by mass or less.

Meanwhile, the content of the structural unit derived from styrene or styrene derivative in the component (A) correlates with the blending ratio of the styrene or styrene derivative, and thus may be 10 to 60% by mass, 15 to 50% by mass, 30 to 50% by mass, 35 to 50% by mass, or 40 to 50% by mass.

Furthermore, in the component (A), (meth)acrylic acid benzyl ester may be used as a polymerizable monomer from the standpoint of resolution and aspect ratio. The content of the structural unit derived from (meth)acrylic acid benzyl ester in the component (A) may be 15 to 50% by mass, 15 to 45% by mass, 15 to 40% by mass, 15 to 35% by mass, or 20 to 30% by mass from the standpoint of further improving the resolution and aspect ratio.

These binder polymers can be used singly or in combination of two or more kinds thereof. Examples of the component (A) in the case of using two or more kinds in combination include two or more binder polymers composed of different polymerizable monomers, two or more binder polymers having different weight average molecular weights, and two or more binder polymers having different degrees of dispersion.

The component (A) can be produced by a common method. Specifically, the component (A) can be produced, for example, by radical polymerization of (meth)acrylic acid alkyl ester, (meth)acrylic acid, styrene, and the like.

The weight average molecular weight of the component (A) may be 20000 to 300000, 40000 to 150000, 40000 to 120000, or 50000 to 80000 from the standpoint of improving the mechanical strength and alkali developability in a well-balanced manner. The developer resistance tends to be excellent when the weight average molecular weight of the component (A) is 20000 or more, and there is a tendency that the development time is prevented from becoming longer when the weight average molecular weight of the component (A) is 300000 or less. Noted that, the weight average molecular weight in this specification is measured by gel permeation chromatography (GPC), and is a value calculated using a calibration curve created using standard polystyrene.

The content of the component (A) may be 30 to 80 parts by mass, 40 to 75 parts by mass, 50 to 70 parts by mass, or 50 to 60 parts by mass with respect to 100 parts by mass of the total solid component amount in the component (A) and the component (B) described below. When the content of the component (A) is in this range, the coating properties of the photosensitive resin composition and the strength of the photocured portion are more favorable.

### ((B) Photopolymerizable Compound)

The photosensitive resin composition according to the present embodiment may contain (B) a photopolymerizable compound (hereinafter also referred to as “component (B)”). As the component (B), any compound can be used without particular limitation as long as it is a photopolymerizable compound or a photocrosslinkable compound, but for example, a compound having at least one ethylenically unsaturated bond in the molecule can be used.

As the component (B), a bisphenol type (meth)acrylate compound may be contained. Examples of the bisphenol type (meth)acrylate compound include 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane. These can be used singly or in combination of two or more kinds thereof. Furthermore, as the bisphenol type (meth)acrylate compound, 2,2-bis(4-(methacryloxypentaethoxy)phenyl)propane and 2,2-bis(4-(methacryloxydiethoxy)phenyl)propane may be contained.

Examples of commercially available bisphenol type (meth)acrylate compounds include 2,2-bis(4-(methacryloxydiethoxy)phenyl)propane (“BPE-200” manufactured by SHIN-NAKAMURA CHEMICAL Co., Ltd.), 2,2-bis(4-(methacryloxypentaethoxy)phenyl)propane (“BPE-500” manufactured by SHIN-NAKAMURA CHEMICAL Co., Ltd. or “FA-321M” manufactured by Showa Denko Materials Co., Ltd.), 2,2-bis(4-(methacryloxypentadecaethoxy)phenyl)propane (“BPE-1300” manufactured by SHIN-NAKAMURA CHEMICAL Co., Ltd.), and 2,2-bis(4-(methacryloxypolyethoxy)phenyl)propane (“BP-2EM” manufactured by Kyoeisha Chemical Co., Ltd. (EO group: 2.6 (average value))

The content of the bisphenol type (meth)acrylate compound may be 1 to 50% by mass, 3 to 40% by mass, 10 to 40% by mass, 20 to 40% by mass, or 30 to 40% by mass with respect to the total solid component amount in the component (A) and component (B) from the standpoint of further improving chemical resistance.

Furthermore, the content of the bisphenol type (meth)acrylate compound may be 30 to 99% by mass, 50 to 97% by mass, 60 to 95% by mass, 70 to 95% by mass, or 80 to 90% by mass with respect to the total solid component amount in the component (B) from the standpoint of further improving chemical resistance.

The content of the component (B) may be 20 to 70 parts by mass, 25 to 60 parts by mass, or 30 to 50 parts by mass with respect to 100 parts by mass of the total solid component amount in the component (A) and component (B). When the content of the component (B) is in this range, the photosensitivity and coating properties are also more favorable in addition to the resolution, adhesive properties and suppressibility of the generation of resist footing of the photosensitive resin composition.

((C) Photopolymerization initiator)

The photosensitive resin composition according to the present embodiment may contain at least one (C) photopolymerization initiator (hereinafter also referred to as “component (C)”). The component (C) is not particularly limited as long as it can polymerize the component (B), and can be appropriately selected from commonly used photopolymerization initiators.

Examples of the component (C) include aromatic ketones such as 2-benzyl-2-dimethylamino-1-(4-morpholinophenyl)-butanone-1 and 2-methyl-1-[4-(methylthio)phenyl]-2-morpholino-propanone-1, quinones such as alkyl anthraquinones, benzoin ether compounds such as benzoin alkyl ethers, benzoin compounds such as benzoin and alkylbenzoins, benzyl derivatives such as benzyl dimethyl ketal, 2,4,5-triarylimidazole dimers such as 2-(o-chlorophenyl)-4,5-diphenylimidazole dimer and 2-(o-fluorophenyl)-4,5-diphenylimidazole dimer, and acridine derivatives such as 9-phenylacridine and 1,7-(9,9′-acridinyl) heptane. These can be used singly or in combination of two or more kinds thereof.

Among these, a 2,4,5-triarylimidazole dimer may be contained from the viewpoint of improving resolution. Examples of the 2,4,5-triarylimidazole include dimer 2-(o-chlorophenyl)-4,5-diphenylimidazole dimer, 2-(o-chlorophenyl)-4,5-bis-(m-methoxyphenyl) imidazole dimer, and 2-(p-methoxyphenyl)-4,5-diphenylimidazole dimer. Among these, 2-(o-chlorophenyl)-4,5-diphenylimidazole dimer may be contained from the viewpoint of improving photosensitivity stability.

As the 2,4,5-triarylimidazole dimer, for example, 2,2′-bis(2-chlorophenyl)-4,4′,5,5′-tetraphenylbiimidazole is commercially available as B-CIM (manufactured by Hodogaya Chemical Co., Ltd., product name).

The component (C) may include at least one of 2,4,5-triarylimidazole dimers or may include 2-(2-chlorophenyl)-4,5-diphenylimidazole dimer from the viewpoint of further improving the photosensitivity and adhesive properties and further suppressing the light absorbability of the component (C). Noted that, the structure of 2,4,5-triarylimidazole dimer may be symmetric or asymmetric.

The content of the component (C) may be 0.01 to 30 parts by mass, 0.1 to 10 parts by mass, 1 to 7 parts by mass, 1 to 6 parts by mass, 1 to 5 parts by mass, or 2 to 5 parts by mass with respect to 100 parts by mass of the total solid component amount in the component (A) and component (B). The photosensitivity, resolution, and adhesive properties tend to be improved when the content of the component (C) is 0.01 part by mass or more, and the resist pattern shape tends to be excellent when the content of the component (C) is 30 parts by mass or less.

### ((D) Photosensitizer)

The photosensitive resin composition according to the present embodiment may contain (D) a photosensitizer (hereinafter also referred to as “component (D)”). By containing the component (D), there is a tendency that the absorption wavelength of active light rays used for exposure can be effectively utilized.

Examples of the component (D) include pyrazolines, dialkylaminobenzophenones, anthracenes, coumarins, acridines, xanthones, oxazoles, benzoxazoles, thiazoles, benzothiazoles, triazoles, stilbenes, triazines, thiophenes, naphthalimides and triarylamines. These can be used singly or in combination of two or more kinds thereof. From the standpoint of being possible to more effectively utilize the absorption wavelength of active light rays used for exposure, the component (D) may include pyrazolines, anthracenes, coumarins, acridines or dialkylaminobenzophenones, among these, coumarins, acridines or dialkylaminobenzophenones may be included, and dialkylaminobenzophenones may be included. Examples of commercially available dialkylaminobenzophenones include “EAB” manufactured by Hodogaya Chemical Co., Ltd.

In the case of containing the component (D), the content thereof may be 1.0 part by mass or less, 0.5 parts by mass or less, 0.15 parts by mass or less, 0.12 parts by mass or less, or 0.10 parts by mass or less with respect to 100 parts by mass of the total solid component amount in the component (A) and component (B). When the content of the component (D) is 1.0 part by mass or less with respect to 100 parts by mass of the total solid component amount in the component (A) and component (B), there is a tendency that deterioration of the resist pattern shape and the generation of resist footing can be suppressed and more favorable resolution can be achieved. Furthermore, the content of the component (D) may be 0.01 part by mass or more with respect to 100 parts by mass of the total solid component amount in the component (A) and component (B) from the standpoint of being likely to obtain high photosensitivity and favorable resolution.

### ((E) Polymerization Inhibitor)

The photosensitive resin composition according to the present embodiment may contain (E) a polymerization inhibitor (hereinafter also referred to as “component (E)”). By containing the component (E), there is a tendency that the exposure dose necessary to photocure the photosensitive resin composition can be adjusted to the exposure dose that is optimal for exposure using a projection exposure machine. Examples of the component (E) include catechol, resorcinol, 1,4-hydroquinone, alkylcatechols such as 2-methylcatechol, 3-methylcatechol, 4-methylcatechol, 2-ethylcatechol, 3-ethylcatechol, 4-ethylcatechol, 2-propylcatechol, 3-propylcatechol, 4-propylcatechol, 2-n-butylcatechol, 3-n-butylcatechol, 4-n-butylcatechol, 2-tert-butylcatechol, 3-tert-butylcatechol, 4-tert-butylcatechol, and 3,5-di-tert-butylcatechol, alkylresorcinols such as 2-methylresorcinol, 4-methylresorcinol, 5-methylresorcinol (orcine), 2-ethylresorcinol, 4-ethylresorcinol, 2-propylresorcinol, 4-propylresorcinol, 2-n-butylresorcinol, 4-n-butylresorcinol, 2-tert-butylresorcinol and 4-tert-butylresorcinol, alkylhydroquinones such as methylhydroquinone, ethylhydroquinone, propylhydroquinone, tert-butylhydroquinone, and 2,5-di-tert-butylhydroquinone, pyrogallol and phloroglucin. These can be used singly or in combination of two or more kinds thereof.

### (Other Components)

In the photosensitive resin composition according to the present embodiment, if necessary, additives, for example, dyes such as malachite green, victoria pure blue, brilliant green and methyl violet, photochromic agents such as tribromophenyl sulfone, Leucocrystal Violet, diphenylamine, benzylamine, triphenylamine, diethylaniline, and o-chloroaniline, thermal coloring inhibitors, plasticizers such as p-toluenesulfonamide, pigments, fillers, antifoaming agents, flame retardants, adhesive property imparting agents, leveling agents, peeling accelerators, antioxidants, fragrances, imaging agents, and thermal crosslinking agents can each be contained at 0.01 to 20 parts by mass with respect to 100 parts by mass of the total solid component amount in the component (A) and component (B). These additives can be used singly or in combination of two or more kinds thereof.

Furthermore, the photosensitive resin composition according to the present embodiment can contain at least one organic solvent, if necessary, in order to improve the handling properties of the photosensitive composition and adjust the viscosity and storage stability. As the organic solvent, commonly used organic solvents can be used without particular limitation. Specific examples thereof include organic solvents such as methanol, ethanol, acetone, methyl ethyl ketone, methyl cellosolve, ethyl cellosolve, toluene, N,N-dimethylformamide, and propylene glycol monomethyl ether, and mixed solvents thereof. These can be used singly or in combination of two or more kinds thereof.

### <Protective Layer>

In the photosensitive element of the present embodiment, a protective layer can also be laminated on the surface of the photosensitive layer opposite to the surface in contact with the barrier layer. As the protective layer, for example, a polymer film such as polyethylene or polypropylene may be used. Furthermore, a polymer film similar to the support film described above may be used, or a polymer film different from the support film may be used.

Hereinafter, a method for manufacturing a photosensitive element in which a support film, a barrier layer, a photosensitive layer and a protective layer are sequentially laminated will be described.

### <Method for Manufacturing Photosensitive Element>

First, for example, a water-soluble resin containing polyvinyl alcohol is gradually added to a mixed solvent of water and an organic solvent used if necessary heated to 70 to 90° C. so that the solid content is 10 to 20% by mass, stirring was performed for about one hour, and then, if necessary, other components such as a leveling agent are mixed and uniformly dissolved to obtain a resin composition for barrier layer formation. In this specification, “solid components” refer to nonvolatile components of a resin composition excluding volatile substances such as water and organic solvents. In other words, “solid components” refer to components, which do not volatilize but remain during the drying step, other than solvents such as water and organic solvents, and include liquid, starch syrup-like, and wax-like substances at room temperature about 25° C.

Next, the resin composition for barrier layer formation is applied onto the support film and dried to form a barrier layer. The application of the resin composition for barrier layer formation onto the support film can be performed, for example, by known methods such as roll coating, comma coating, gravure coating, air knife coating, die coating, bar coating, and spray coating.

Furthermore, drying of the applied resin composition for barrier layer formation is not particularly limited as long as at least part of the solvent such as water can be removed, and may be performed at 70 to 150° C. for 5 to 30 minutes. After drying, the amount of the solvent remaining in the barrier layer may be 2% by mass or less from the standpoint of preventing diffusion of the solvent in subsequent steps.

Next, a photosensitive resin composition may be applied onto the barrier layer of the support film on which the barrier layer has been formed in the same manner as for the application of the resin composition for barrier layer formation, and dried to form a photosensitive layer on the barrier layer. Next, a protective layer is laminated on the photosensitive layer thus formed, whereby a photosensitive element including a support film, a barrier layer, a photosensitive layer, and a protective layer in this order can be manufactured. In addition, by bonding a barrier layer formed on a support film and a photosensitive layer formed on a protective layer together, a photosensitive element including a support film, a barrier layer, a photosensitive layer, and a protective layer in this order may be obtained.

The thickness of the photosensitive layer in the photosensitive element can be appropriately selected depending on the use, but may be 1 μm or more, 5 μm or more, or 10 μm or more as the thickness after drying or may be 200 μm or less, 100 μm or less, 50 μm or less, or less than 20 μm as the thickness after drying. As the thickness of the photosensitive layer is 1 μm or more, 5 μm or more, or 10 μm or more, industrial coating becomes easier and productivity tends to be improved. Furthermore, in a case where the thickness of the photosensitive layer is 200 μm or less, 100 μm or less, 50 μm or less, or less than 20 μm, photosensitivity is high and photocurability at the resist bottom is excellent, and there is thus a tendency that a resist pattern excellent in resolution and aspect ratio can be formed.

The melt viscosity at 110° C. of the photosensitive layer in the photosensitive element can be appropriately selected depending on the kind of base material (base) in contact with the photosensitive layer, but may be 50 to 10000 Pa·s, 100 to 5000 Pa·s, or 200 to 1000 Pa·s at 110° C. after drying. When the melt viscosity at 110° C. is 50 Pa·s or more, wrinkles and voids are not generated in the lamination step, and productivity tends to be improved. Furthermore, when the melt viscosity at 110° C. is 10000 Pas or less, the adhesiveness with the base is improved in the lamination step, and defective adhesion tends to be reduced.

The form of the photosensitive element according to the present embodiment is not particularly limited. For example, the photosensitive element may be in the form of a sheet or in the form of a roll wound around a core. In the case of winding the photosensitive element into a roll, the photosensitive element may be wound up with the support film on the outside. Examples of the material for the core include plastics such as a polyethylene resin, a polypropylene resin, a polystyrene resin, a polyvinyl chloride resin or an ABS resin (acrylonitrile-butadiene-styrene copolymer).

On the end face of the roll-shaped photosensitive element roll obtained in this way, an end face separator may be installed from the standpoint of end face protection, or a moisture-proof end face separator may be installed from the standpoint of edge fusion resistance. As a packaging method, the photosensitive element roll may be wrapped in a black sheet with low moisture permeability.

The photosensitive element according to the present embodiment can be suitably used, for example, in a method for forming a resist pattern and a method for manufacturing a printed wiring board to be described later.

### [Method for Forming Resist Pattern]

The method for forming a resist pattern according to the present embodiment includes (i) a step of disposing a photosensitive layer, a barrier layer, and a support film on a substrate in this order from the substrate side using the above-described photosensitive element (hereinafter also referred to as “(i) photosensitive layer and barrier layer forming step”), (ii) a step of removing the support film and exposing the photosensitive layer to active light rays through the barrier layer (hereinafter also referred to as “(ii) exposure step”), and (iii) a step of removing the barrier layer and an uncured portion of the photosensitive layer from the substrate (hereinafter also referred to as “(iii) development step”), and may include other steps if necessary. Noted that, the resist pattern can be said to be a pattern of a photocured product of a photosensitive resin composition, or a relief pattern. Furthermore, depending on the purpose, the resist pattern in the present embodiment may be used as a resist or for other uses such as a protective film.

### ((i) Photosensitive Layer and Barrier Layer Forming Step)

In the photosensitive layer and barrier layer forming step, a photosensitive layer and a barrier layer are formed on the substrate using the photosensitive element described above. The substrate is not particularly limited, but usually a substrate for circuit formation including an insulating layer and a conductor layer formed on the insulating layer, a die pad (base material for lead frame) such as an alloy base material, or the like is used.

As a method for forming a photosensitive layer and a barrier layer on a substrate, for example, in the case of using a photosensitive element having a protective layer, a photosensitive layer and a barrier layer can be formed on the substrate by removing the protective layer and then press bonding the photosensitive layer of the photosensitive element to the substrate while performing heating. A laminate including a substrate, a photosensitive layer, a barrier layer, and a support film in this order is thus obtained.

In the case of performing the photosensitive layer and barrier layer forming step using a photosensitive element, the step may be performed under reduced pressure from the standpoint of adhesive properties and followability. Heating during press bonding may be performed at a temperature of 70 to 130° C., and press bonding may be performed at a pressure of 0.1 to 1.0 MPa (1 to 10 kgf/cm²), but these conditions can be appropriately selected if necessary. Noted that, when the photosensitive layer of the photosensitive element is heated to 70 to 130° C., it is not necessary to preheat the substrate in advance, but the substrate can also be preheated in order to further improve adhesive properties and followability.

((ii) Exposure Step)

In the exposure step, the support film is removed and the photosensitive layer is exposed to active light rays through the barrier layer. Thus, the exposed portion irradiated with active light rays may be photocured and a photocured portion (latent image) may be formed, or the unexposed portion that is not irradiated with active light rays may be photocured and a photocured portion may be formed. In a case where a photosensitive layer and a barrier layer are formed using the above-described photosensitive element, the support film present on the photosensitive layer is peeled off and then exposure is performed. By exposing the photosensitive layer through the barrier layer, a resist pattern excellent in resolution and resist pattern shape can be formed.

As the exposure method, a known exposure method can be applied, and examples thereof include a method in which the image shape is irradiated with active light rays through a negative or positive mask pattern called artwork (mask exposure method), an LDI (laser direct imaging) exposure method, or a method in which the image shape is irradiated with active light rays onto which the image of a photomask is projected through a lens (projection exposure method). Among these, a projection exposure method may be used from the viewpoint of excellent resolution. In other words, the photosensitive element and the like according to the present embodiment are applied to a projection exposure method. Noted that, the projection exposure method can also be said to be an exposure method using active light rays with attenuated energy.

The source of active light rays is not particularly limited as long as it is a commonly used and known light source, and for example, carbon arc lamps, mercury vapor arc lamps, ultra-high pressure mercury lamps, high pressure mercury lamps, xenon lamps, gas lasers such as argon lasers, solid-state lasers such as YAG lasers, semiconductor lasers such as gallium nitride-based blue-violet lasers, and the like that effectively emit ultraviolet rays are used. Furthermore, photo flood light bulbs, solar lamps, and the like that effectively emit visible light may also be used. Among these, from the viewpoint of improving resolution and alignment performance in a well-balanced manner, a light source capable of emitting i-line monochromatic light having an exposure wavelength of 365 nm, a light source capable of emitting h-line monochromatic light having an exposure wavelength of 405 nm, or a light source capable of emitting active light rays at the exposure wavelength of ihg-mixed line may be used, and among these, a light source capable of emitting i-line monochromatic light having an exposure wavelength of 365 nm may be used. Examples of the light source capable of emitting i-line monochromatic light having an exposure wavelength of 365 nm include ultra-high pressure mercury lamps.

((iii) Development Step)

In the development step, the barrier layer and the uncured portion of the photosensitive layer are removed from the substrate. Through the development step, a resist pattern consisting of a photocured portion obtained by photocuring the photosensitive layer is formed on the substrate. In a case where the barrier layer is water-soluble, the barrier layer may be washed with water for removal, and then the uncured portions other than the photocured portions may be removed using a developer, and in a case where the barrier layer is soluble in a developer, the barrier layer may be removed with the developer together with the uncured portions other than the photocured portions. The development method includes wet development.

In the case of wet development, development can be carried out by a known wet development method using a developer compatible with the photosensitive resin composition. Examples of wet development methods include dipping method, paddle method, high pressure spraying method, and methods using brushing, slapping, scrubbing, shaking immersion, and the like, and a high pressure spraying method is most suitable from the viewpoint of improving resolution. These wet development methods may be used singly or in combination of two or more kinds thereof for development.

The developer is appropriately selected depending on the configuration of the photosensitive resin composition. Examples thereof include alkaline aqueous solutions and organic solvent developers.

From the standpoint of safety, stability, and favorable operability, alkaline aqueous solutions may be used as the developer. As the base for the alkaline aqueous solution, for example, alkali hydroxides such as hydroxides of lithium, sodium or potassium, alkali carbonates such as carbonates or bicarbonates of lithium, sodium, potassium or ammonium, alkali metal phosphates such as potassium phosphate and sodium phosphate, alkali metal pyrophosphates such as sodium pyrophosphate and potassium pyrophosphate, sodium borate, sodium metasilicate, tetramethylammonium hydroxide, ethanolamine, ethylenediamine, diethylenetriamine, 2-amino-2-hydroxymethyl-1,3-propanediol, 1,3-diamino-2-propanol and morpholine are used.

As the alkaline aqueous solutions used for development, for example, a 0.1 to 5% by mass dilute solution of sodium carbonate, a 0.1 to 5% by mass dilute solution of potassium carbonate, a 0.1 to 5% by mass dilute solution of sodium hydroxide, and a 0.1 to 5% by mass dilute solution of sodium tetraborate can be used. Furthermore, the pH of the alkaline aqueous solution used for development may be in the range of 9 to 11, and the temperature of the alkaline aqueous solution can be adjusted according to the developability of the photosensitive layer. In addition, for example, a surfactant, an antifoaming agent, and a small amount of an organic solvent for accelerating development may be mixed into the alkaline aqueous solution. Noted that, examples of the organic solvent used in the alkaline aqueous solution include 3-acetone alcohol, acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether and diethylene glycol monobutyl ether.

Examples of the organic solvent used in the organic solvent developer include 1,1,1-trichloroethane, N-methylpyrrolidone, N,N-dimethylformamide, cyclohexanone, methyl isobutyl ketone and γ-butyrolactone. From the viewpoint of preventing ignition, water may be added to these organic solvents in the range of 1 to 20% by mass to prepare an organic solvent developer.

### (Other Steps)

The method for forming a resist pattern according to the present embodiment may include a step of further curing the resist pattern by removing the uncured portions in the development step and then, if necessary, performing heating at 60 to 250° C. or exposure at an exposure dose of 0.2 to 10 J/cm².

### [Method for Manufacturing Printed Wiring Board]

The method for manufacturing a printed wiring board according to the present embodiment includes a step of forming a conductor pattern by etching or plating a substrate on which a resist pattern is formed by the method for forming a resist pattern described above, and may include other steps such as a resist pattern removing step, if necessary. The method for manufacturing a printed wiring board according to the present embodiment can be suitably used to form a conductor pattern by using the method for forming a resist pattern using a photosensitive element. Among these, application to a method for forming a conductor pattern by plating is more suitable. Noted that, a conductor pattern can also be called a circuit.

In etching, the conductor layer of the substrate that is not covered with the resist is etched away using a resist pattern formed on a substrate having a conductor layer as a mask to form a conductor pattern.

The etching method is appropriately selected depending on the conductor layer to be removed. Examples of the etching solution include a cupric chloride solution, a ferric chloride solution, an alkaline etching solution, and a hydrogen peroxide-based etching solution, and a ferric chloride solution may be used from the viewpoint of favorable etch factor.

Meanwhile, in plating, copper, solder, or the like is plated on the conductor layer of the substrate that is not covered with the resist using a resist pattern formed on a substrate having a conductor layer as a mask. After plating, the resist is removed by the resist pattern removal to be described later, and the conductor layer covered with the resist is further etched to form a conductor pattern.

The plating method may be electrolytic plating or electroless plating, but may be electroless plating among these. Examples of electroless plating include copper plating such as copper sulfate plating and copper pyrophosphate plating, solder plating such as high-slow solder plating, Watts bath (nickel sulfate-nickel chloride) plating, nickel plating such as nickel sulfamate plating, and gold plating such as hard gold plating and soft gold plating.

After the etching or plating, the resist pattern on the substrate is removed. The resist pattern can be removed by peeling, for example, using an aqueous solution that is more strongly alkaline than the alkaline aqueous solution used in the above-described development step. As this strong alkaline aqueous solution, for example, a 1 to 10% by mass aqueous sodium hydroxide solution and a 1 to 10% by mass aqueous potassium hydroxide solution are used. Among these, a 1 to 5% by mass aqueous sodium hydroxide solution or aqueous potassium hydroxide solution may be used.

Examples of the resist pattern removing method include an immersion method and a spraying method. These may be used singly or concurrently.

In a case where the resist pattern is removed after plating, a desired printed wiring board can be manufactured by further etching the conductor layer covered with the resist by etching and thus forming a conductor pattern. The etching method at this time is appropriately selected depending on the conductor layer to be removed. For example, the above-mentioned etching solution can be applied.

The method for manufacturing a printed wiring board according to the present embodiment is applicable not only to the manufacture of single layer printed wiring boards but also to the manufacture of multilayer printed wiring boards, and is also applicable to the manufacture of printed wiring boards having small-diameter through holes.

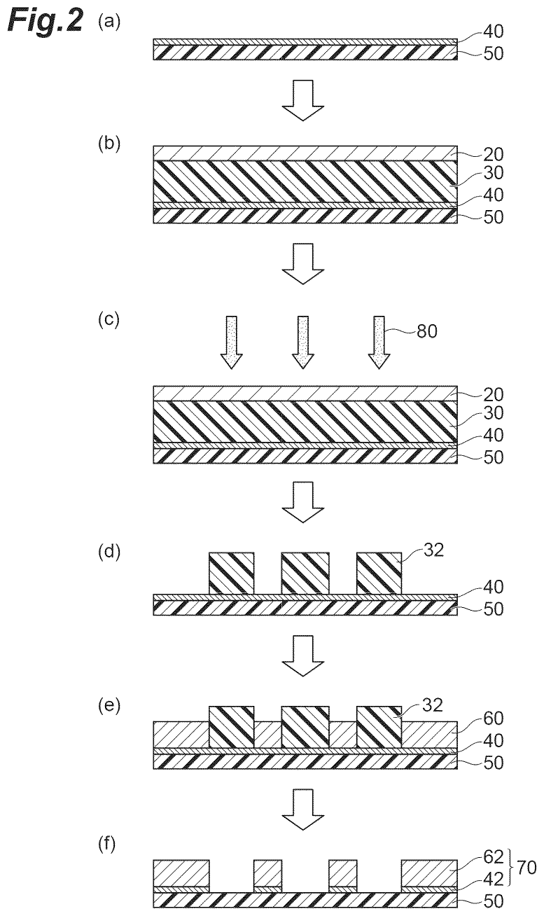

The method for manufacturing a printed wiring board according to the present embodiment can be suitably used for manufacture of a high-density package substrate, particularly for manufacture of a wiring board by a semi-additive process. Noted that, an example of the step of manufacturing a wiring board by a semi-additive process is illustrated in FIG. 2.

In FIG. 2(a), a substrate (substrate for circuit formation) in which a conductor layer 40 is formed on an insulating layer 50 is prepared. The conductor layer 40 is, for example, a copper layer. In FIG. 2(b), by the photosensitive layer and barrier layer forming step, a photosensitive layer 30 and a barrier layer 20 are formed on the conductor layer 40 of the substrate. In FIG. 2(c), by the exposure step, a photocured portion is formed in the photosensitive layer 30 by irradiating the photosensitive layer 30 with active light rays 80 onto which the image of a photomask is projected through the barrier layer 20. In FIG. 2(d), by the development step, a resist pattern 32, which is a photocured portion, is formed on the substrate by removing the region (including the barrier layer) other than the photocured portion formed by the exposure step from the substrate. In FIG. 2(e), a plating layer 60 is formed on the conductor layer 40 of the substrate that is not covered with the resist by plating using the resist pattern 32, which is the photocured portion, as a mask. In FIG. 2(f), the resist pattern 32, which is a photocured portion, is peeled off with a strong alkaline aqueous solution, and then the conductor layer 40 that is masked with the resist pattern 32 is removed by flash etching to form a conductor pattern 70 including an etched plating layer 62 and an etched conductor layer 42. The materials for the conductor layer 40 and the plating layer 60 may be the same as or different from each other. In a case where the materials for the conductor layer 40 and the plating layer 60 are the same as each other, the conductor layer 40 and the plating layer 60 may be integrated. Noted that, in FIG. 2, the projection exposure method has been described, but the resist pattern 32 may be formed using a mask exposure method and an LDI exposure method concurrently.

Suitable embodiments of the present disclosure have been described above, but the present disclosure is not limited to the embodiments in any way.

### EXAMPLES

Hereinafter, the present disclosure will be described more specifically based on Examples, but the present disclosure is not limited to the following Examples. Noted that, unless otherwise stated, “parts” and “%” are based on mass.

### <Synthesis of Binder Polymer A-1>

A solution (a) was prepared by mixing 270 g of methacrylic acid, 500 g of styrene, 200 g of benzyl methacrylate, and 30 g of 2-hydroxyethyl methacrylate, which were polymerizable monomers, with 9 g of azobisisobutyronitrile. In addition, a solution (b) was prepared by mixing 1.4 g of azobisisobutyronitrile with a liquid mixture of 160 g of 1-methoxy-2-propanol and 120 g of toluene. A liquid mixture of 450 g of 1-methoxy-2-propanol and 380 g of toluene was put into a flask equipped with a stirrer, a reflux condenser, a thermometer, a dropping funnel, and a nitrogen gas introduction tube, and then stirred while blowing nitrogen gas into the flask, and the temperature was raised to 80° C. The solution (a) was added dropwise to the liquid mixture in the flask over 4 hours at a constant dropping rate, and then stirring was performed at 80° C. for 2 hours. Next, the solution (b) was added dropwise to the solution in the flask over 10 minutes at a constant dropping rate, and then the solution in the flask was stirred at 80° C. for 3 hours. Furthermore, the temperature of the solution in the flask was raised to 90° C. over 30 minutes and kept at 90° C. for 6 hours, then stirring was stopped, and the solution was cooled to room temperature (25° C.) to obtain a solution of binder polymer A-1. The nonvolatile component content (solid content) in the solution of binder polymer A-1 was 49% by mass. In addition, the weight average molecular weight (Mw) of binder polymer A-1 was 35000.

Meanwhile, the weight average molecular weight was determined by performing measurement by gel permeation chromatography (GPC) and calculation using the calibration curve of standard polystyrene. The conditions for GPC are as shown below.

### (GPC Conditions)

Column: Gelpack GL-R440, Gelpack GL-R450 and Gelpack GL-R400M (all manufactured by Showa Denko Materials Co., Ltd.) connected
Eluent: Tetrahydrofuran
Measurement temperature: 40° C.
Flow rate: 2.05 mL/min
Detector: Hitachi L-2490 RI (Hitachi, Ltd.)

### <Preparation of Resin Composition for Barrier Layer Formation>

A resin composition for barrier layer formation was obtained by mixing the respective components shown in Table 1 below in the amounts (unit: parts by mass) shown in the same table. Specifically, a water-soluble resin was gradually added to a solvent at room temperature, after the entire amount was added, stirring was performed for 1 hour, and then a leveling agent was mixed and uniformly dissolved to obtain a resin composition for barrier layer formation. Noted that, the amount of water-soluble resin blended in Table 1 is a blended amount in terms of solid component.

### <Preparation of Photosensitive Resin Composition>

Next, a photosensitive resin composition was obtained by mixing the respective components shown in Table 1 below in the amounts (unit: parts by mass) shown in the same table. Noted that, the amount of the binder polymer blended in Table 1 is a blended amount in terms of solid component.

TABLE 1

| | | | Blended |
|---|---|---|---|
| | | | amount |
| | | | (parts |
| Composition | Component | Material | by mass) |
| Resin composition | Water-soluble resin | HC-100G*¹ | 65.0 |
| for barrier | | K-30*² | 40.0 |
| layer formation | Leveling agent | WS-314*³ | 0.325 |
| | Solvent | Isopropyl | 260 |
| | | alcohol | |
| | | Water | 75.6 |
| Photosensitive resin | (A) binder polymer | A-1*⁴ | 57.0 |
| composition | (B) | FA-321M*⁵ | 34.5 |
| | photopolymerizable | FA-024*⁶ | 2.5 |
| | compound | BP-2EM*⁷ | 6.0 |
| | (C) | B-CIM*⁸ | 5.5 |
| | photopolymerization | | |
| | initiator | | |
| | (D) photosensitizer | PZ-501D*⁹ | 0.027 |
| | (E) polymerization | Q-TBC-5P*¹⁰ | 0.04 |
| | inhibitor | LA-7RD*¹¹ | 0.01 |
| | Other components | Leucocrystal | 0.77 |
| | | Violet*¹² | |
| | | SF-808H*¹³ | 1.0 |
| | | Malachite | 0.05 |
| | | green*¹⁴ | |
| | Solvent | Methanol | 6 |
| | | Toluene | 16 |
| | | Acetone | 10 |

Details of the respective components in Table 1 are as follows.
(Water-soluble resin)
*¹HC-100G (polyvinyl alcohol, manufactured by Taiseikayaku Co., Ltd., product name: MARUTITE HC-100G, solid content 13.5% by mass)
*²K-30 (polyvinylpyrrolidone, manufactured by NIPPON SHOKUBAI CO., LTD., product name)
(Leveling agent)
*³WS-314 (acrylic polymer, manufactured by Kyoeisha Chemical Co., Ltd., product name, components: acrylic polymer 48% by mass and 3-methoxy-3-methyl-1-butanol 52% by mass, composition of acrylic polymer: copolymer of about 6.89 mol % of butyl (meth)acrylate, about 61.4 mol % of isobutyl (meth)acrylate, and about 31.7 mol % of terminal methoxy group EO-modified (meth)acrylate)
Component (A): Binder polymer
*⁴A-1 (binder polymer A-1 obtained in Synthesis Example 1)
Component (B): Photopolymerizable compound
*⁵FA-321M (manufactured by Showa Denko Materials Co., Ltd., product name)
2,2-Bis(4-(methacryloxypolyethoxy)phenyl)propane (ethylene oxide average 10 mol adduct)
*⁶FA-024M (manufactured by Showa Denko Materials Co., Ltd., product name)
(PO)(EO)(PO) modified dimethacrylate (ethylene oxide average 6 mol and propylene oxide average 12 mol adduct (total value))
*⁷BP-2EM (manufactured by Kyoeisha Chemical Co., Ltd., product name)
2,2-Bis(4-(methacryloxypolyethoxy)phenyl)propane (EO group: 2.6 (total value))
Component (C): Photopolymerization initiator
*⁸B-CIM (manufactured by Hodogaya Chemical Co., Ltd., product name)
2,2′-Bis(2-chlorophenyl)-4,4′,5,5′-tetraphenylbiimidazole
Component (D): Photosensitizer
*⁹PZ-501D (manufactured by NIPPON CHEMICAL WORKS CO., LTD., product name)
1-Phenyl-3-(4-methoxystyryl)-5-(4-methoxyphenyl)-pyrazoline
Component (E): Polymerization inhibitor
*¹⁰Q-TBC-5P (manufactured by DIC Corporation, product name)
4-tert-Butylcatechol
*¹¹LA-7RD (manufactured by ADEKA Corporation, product name)
4-Hydroxy-2,2,6,6-tetramethylpiperidine-N-oxyl
Other components
*¹²Leucocrystal Violet (Yamada Chemical Co., Ltd.) (color former)
*¹³SF-808H (manufactured by SANWA KASEI CORP., product name)
(adhesiveness imparting agent)
Mixture of carboxybenzotriazole, 5-amino-1H-tetrazole and methoxypropanol
*¹⁴Malachite green (manufactured by OSAKA ORGANIC CHEMICAL INDUSTRY LTD.) (dye)

### Examples 1 to 3 and Comparative Examples 1 and 3

### <Fabrication of Photosensitive Element>

### (Preparation of Support Film)

As support films for photosensitive elements, five kinds of PET films A to E containing a lubricant (particles) were prepared. The thicknesses of the PET films A to E are all 16 μm. Furthermore, the sizes and contents of the lubricants (particles) contained in the PET films A to E are different from one another. The following measurements were performed on the PET films A to E. The results are shown in Table 2.

[Number of Particles with Diameter of 0.8 μm or More]

The number of particles with a diameter of 0.8 μm or more per 0.0225 mm² on the surface F1 of the PET films A to E on the side where the barrier layer or photosensitive layer is to be formed was measured using a laser microscope under the following conditions.

### —Measurement Conditions—

Instrument: Hybrid laser microscope (manufactured by Lasertec Corporation, product name: OPTELICS HYBRID)
Measurement range: 150 μm square
Measurement details: A luminance image of the surface F1 of the PET film was acquired. The acquired luminance image was binarized and the size and number of particles (lubricant) were measured. The number of particles with a diameter of 0.8 μm or more in the measurement range of 150 μm square (0.0225 mm²) was calculated. The measurement was performed five times, and the average value was taken as the number of particles.
   [Number of Particles with Diameter of 5.0 μm or More]

The number of particles with a diameter of 5.0 μm or more per 0.0225 mm² on the surface F1 of the PET films A to E on the side where the barrier layer or photosensitive layer is to be formed was measured in the same manner as for the measurement of the number of particles with a diameter of 0.8 μm or more described above.

### [Haze]

The haze of the PET films A to E was measured using a turbidity meter (manufactured by NIPPON DENSHOKU INDUSTRIES CO., LTD., product name “NDH-5000”) in conformity with the method prescribed in JIS K7105.

### [Coefficient of Linear Thermal Expansion in TD Direction]

The coefficient of linear thermal expansion of the PET films A to E in the TD direction was measured by the following method. First, a test piece was obtained by cutting the PET film into a size of 3 mm×30 mm so that the TD direction was the longitudinal direction. The test piece was set in a thermomechanical analyzer (manufactured by Seiko Instruments Inc., model SSC5200) in tension mode with a distance between chucks of 20 mm. The set test piece was treated under conditions of a temperature range of 20 to 250° C. and a rate of temperature rise of 5° C./min, and the coefficient of linear thermal expansion of the test piece in the TD direction was measured. From the measurement results, the coefficient of linear thermal expansion at 80 to 110° C. was read. This coefficient of linear thermal expansion is the average value at 80 to 110° C.

### (Fabrication of Barrier Layer)

Next, onto the surface F1 of the PET film (support film), a resin composition for barrier layer formation was applied so as to have a uniform thickness, and dried for 10 minutes in a hot air convection dryer at 95° C. to form a barrier layer having a thickness of 5 μm after drying.

### (Fabrication of Photosensitive Layer)

Next, a photosensitive resin composition was applied onto the barrier layer so as to have a uniform thickness, and dried for 10 minutes in a hot air convection dryer at 100° C. to form a photosensitive layer having a thickness of 15 μm after drying.

Next, a polyethylene protective film (protective layer) (manufactured by TAMAPOLY CO., LTD., product name “NF-15A”) was bonded onto this photosensitive layer to obtain a photosensitive element in which a PET film (support film), a barrier layer, a photosensitive layer, and a protective layer were laminated in this order.

### Comparative Example 2

### <Fabrication of Photosensitive Element>

A photosensitive element in which a PET film (support film), a photosensitive layer, and a protective layer were laminated in this order was obtained in the same manner as in Example 2 except that a barrier layer was not provided.

### Comparative Example 4

### <Fabrication of Photosensitive Element>

A photosensitive element in which a PET film (support film), a photosensitive layer, and a protective layer were laminated in this order was obtained in the same manner as in Comparative Example 3 except that a barrier layer was not provided.

### Evaluation

### <Fabrication of Laminate>

A Cu sputtered PET film (manufactured by GEOMATEC Co., Ltd., thickness: 125 μm, Ra<50 nm) as a substrate was heated to 80° C., and while the protective layer was peeled off, each of the photosensitive elements was press-bonded to the substrate so that the photosensitive layer was in contact with the copper surface. The press bonding was performed using a heat roll at 110° C. at a pressure of 0.40 MPa and a roll speed of 1.0 m/min. In this manner, laminates in which a substrate, a photosensitive layer, a barrier layer, and a support film were laminated in this order (Examples 1 to 3 and Comparative Examples 1 and 3) or laminates (Comparative Examples 2 and 4) in which a substrate, a photosensitive layer, and a support film were laminated in this order were obtained. These laminates were used as test pieces in the tests described below. As a laminator, HLM-3000 (manufactured by TAISEI LAMINATOR CO., LTD., product name) was used.

### <Measurement of Minimum Development Time>

The support film was peeled off from the test piece to expose the barrier layer or photosensitive layer, and a 1% by mass aqueous sodium carbonate solution at 30° C. was sprayed. The time until the photosensitive layer was completely removed was measured and taken as the minimum development time.

### <Formation of Resist Pattern>

The support film was peeled off from the test pieces of Examples 1 to 3 and Comparative Examples 1 and 3, a glass chrome type photo tool (one that had a size: 9 cm×9 cm and three types of wiring patterns evenly having line width/space width of 10 μm/10 μm, 15 μm/15 μm, and 20 μm/20 μm or adhesive negative: one that had a wiring pattern having line width/space width of x/x (x: 1 to 18, unit: μm)) as a negative was placed on the exposed barrier layer, and the photosensitive layer was exposed at an exposure dose of 110 mJ/cm² using a projection exposure instrument (manufactured by Ushio Inc., product name “UX-2240-SM-XJ01”) using an ultra-high pressure mercury lamp (365 nm) as a light source. After exposure, a 1% by mass aqueous sodium carbonate solution at 30° C. was sprayed for a time to be two-fold the minimum development time, and the unexposed portions were removed to form a resist pattern. The same operation was performed five times to fabricate five resist patterns for evaluation.

Meanwhile, for the test pieces of Comparative Examples 2 and 4, the photo tool described above was placed on the support film, and the photosensitive layer was exposed through the support film at an exposure dose of 110 mJ/cm² using a projection exposure instrument (manufactured by Ushio Inc., product name “UX-2240-SM-XJ01”) using an ultra-high pressure mercury lamp (365 nm) as a light source. After exposure, the support film was peeled off to expose the photosensitive layer, a 1% by mass aqueous sodium carbonate solution at 30° C. was sprayed for a time to be two-fold the minimum development time, and the unexposed portions were removed to form a resist pattern. The same operation was performed five times to fabricate five resist patterns for evaluation.

### <Measurement of Number of Deletions>

The resist pattern (in a region of 9 cm×9 cm, three types of resist patterns (9 cm in length) having line width/space width of 10 μm/10 μm, 15 μm/15 μm, and 20 μm/20 μm were evenly provided over a width of 9 cm so that the numbers of the resist patterns were the same as one another) formed by the method was inspected using an automatic optical inspection instrument (AOI, manufactured by Nippon Orbotech, product name “Ultra Fusion 600”), and the number of resist deleted portions where the resist was deleted by 5 μm or more was counted. The number of resist deleted portions was counted for the five resist patterns for evaluation, and the total number was taken as the number of deletions. The results are shown in Table 2.

### <Measurement of LER>

The LER (line edge roughness) of the resist pattern formed by the method was measured by the following method.

In other words, using a computer numerical control image measurement system (manufactured by NIKON CORPORATION, product name “NEXIV VMZ-R4540”), an image was taken of a region where a resist pattern having line width/space width of 5 μm/5 μm was formed. By scanning measurement using NEXIV VMZ-R4540, the contour of the resist pattern on the substrate was specified, and the coordinates of the contour of the resist pattern were measured for six lines of the resist pattern. In the measurement of coordinates, the coordinates of 260 points, each having a length of 52 μm divided by 0.2 μm, were measured for each of the contours on one side and the contour on the other side of the line. Furthermore, these measurements were performed at three locations on each of the six lines. The coordinates of a total of 9360 points were thus measured. Then, the variation (3σ) of the contour of the resist pattern was calculated based on the measured coordinates of 9360 points. σ is the standard deviation, and 3σ of the contour of the resist pattern is LER (line edge roughness). The results are shown in Table 2.

### <Evaluation of Lamination Properties>

A copper-clad laminate (manufactured by Showa Denko Materials Co., Ltd., product name “MCL-E-679”, size: 500 mm or more×500 mm or more), which was a glass epoxy material having copper foil (thickness: 35 μm) laminated on both surfaces, was pickled and washed with water, then air-dried, and heated to 80° C. While the protective layer was peeled off, each of the photosensitive elements was press-bonded to the copper-clad laminate so that the photosensitive layer was in contact with the copper surface. The press bonding was performed using a heat roll at 110° C. at a pressure of 0.40 MPa and a roll speed of 1.0 m/min. After the press bonding, the presence or absence of voids between the copper-clad laminate and the photosensitive layer was observed and evaluated based on the following evaluation criteria. The results are shown in Table 2.
A: Voids were not observed.
B: Voids were extremely rarely observed.
C: Voids were rarely observed.

TABLE 2

| | | Example | Example | Example | Comparative | Comparative | Comparative | Comparative |
|---|---|---|---|---|---|---|---|---|
| | | 1 | 2 | 3 | Example 1 | Example 2 | Example 3 | Example 4 |
| Support | Kind of | A | B | C | D | B | E | E |
| film | PET film | | | | | | | |
| | Number of | 17 | 85 | 11 | 160 | 85 | 220 | 220 |
| | particles | | | | | | | |
| | with diameter | | | | | | | |
| | of 0.8 μm | | | | | | | |
| | or more | | | | | | | |
| | (particles) | | | | | | | |
| | Number of | 0 | 0 | 0 | 8 | 0 | 110 | 110 |
| | particles | | | | | | | |
| | with diameter | | | | | | | |
| | of 5.0 μm | | | | | | | |
| | or more | | | | | | | |
| | (particles) | | | | | | | |
| | Haze (%) | <0.5 | <0.5 | <0.5 | 2.2 | <0.5 | <0.5 | <0.5 |
| | Coefficient | 45.6 | 120.0 | 3.24 | 51.1 | 120.0 | 62.2 | 62.2 |
| | of linear | | | | | | | |
| | thermal | | | | | | | |
| | expansion | | | | | | | |
| | in TD | | | | | | | |
| | direction | | | | | | | |
| | (ppm/K) | | | | | | | |

| | | | | | | | |
|---|---|---|---|---|---|---|---|
| Presence or | Presence | Presence | Presence | Presence | Absence | Presence | Absence |
| absence of | | | | | | | |
| barrier layer | | | | | | | |
| Number of | 1 | 0 | 3 | 8 | 37 | 20 | 352 |
| defects | | | | | | | |
| (defects) | | | | | | | |
| LER (nm) | 55 | 71 | 53 | 121 | 160 | 150 | 335 |
| Lamination | B | A | C | B | A | B | B |
| properties | | | | | | | |

### REFERENCE SIGNS LIST

1: photosensitive element, 2: support film, 3, 20: barrier layer, 4, 30: photosensitive layer, 5: protective layer, 32: resist pattern, 40: conductor layer, 42: etched conductor layer, 50: insulating layer, 60: plating layer, 62: etched plating layer, 70: conductor pattern, 80: active light rays.

1. A photosensitive element comprising a support film, a barrier layer, and a photosensitive layer in this order, wherein
a number of particles with a diameter of 0.8 μm or more measured on a surface of the support film on a barrier layer side is 100 or less per 0.0225 mm².

2. The photosensitive element according to claim 1, wherein a number of particles with a diameter of 0.8 μm or more measured on a surface of the support film on a barrier layer side is 5 or more per 0.0225 mm².

3. The photosensitive element according to claim 1, wherein a coefficient of linear thermal expansion of the support film in a TD direction at 80 to 110° C. is 30 ppm/K or more.

4. The photosensitive element according to claim 3, wherein a coefficient of linear thermal expansion of the support film in a TD direction at 80 to 110° C. is 170 ppm/K or less.

5. The photosensitive element according to claim 1, wherein the barrier layer contains a water-soluble resin.

6. The photosensitive element according to claim 1, wherein a thickness of the barrier layer is 2 to 12 μm.

7. The photosensitive element according to claim 1, wherein a number of particles with a diameter of 5.0 μm or more measured on a surface of the support film on a barrier layer side is 0 per 0.0225 mm².

8. A method for forming a resist pattern, the method comprising:
a step of disposing a photosensitive layer, a barrier layer, and a support film on a substrate in this order from a substrate side using the photosensitive element according to claim 1;
a step of removing the support film and exposing the photosensitive layer to active light rays through the barrier layer; and
a step of removing an uncured portion of the photosensitive layer and the barrier layer from the substrate.

9. A method for manufacturing a printed wiring board, the method comprising a step of forming a conductor pattern by etching or plating a substrate on which a resist pattern is formed by the method for forming a resist pattern according to claim 8.
